(19) United States
(12) Patent Application Publication
(10) Pub. No.: US 2026/0166755 A1
(43) Pub. Date: Jun. 18, 2026

(54) Wafer Conveyance Robot

(71) Applicant: Hitachi High-Tech Corporation, Minato-ku, Tokyo (JP)

(72) Inventors: Keiichiro HOSOBUCHI, Tokyo (JP); Kei SHIBAYAMA, Tokyo (JP); Masaya YAMAMOTO, Tokyo (JP)

(21) Appl. No.: 19/126,457

(22) PCT Filed: Nov. 14, 2022
(86) PCT No.: PCT/JP2022/042232

§ 371 Date: May 1, 2025

(51) Int. Cl. B25J 15/06; B25J 11/00; H10P 72/76; H10P 72/78

(52) U.S. Cl. CPC B25J 15/0616; B25J 11/0095; H10P 72/7602; H10P 72/78

(57) ABSTRACT

This wafer conveyance robot which vacuum-suctions a wafer and conveys the same comprises a hand supporting the wafer. The hand has: a first finger and a second finger; a first suction part provided to the first finger; a second suction part provided to the second finger; and a third suction part provided to a connection part connecting the first finger and the second finger. The first suction part, the second suction part, and the third suction part have a first intake hole, a second intake hole, and a third intake hole, respectively. The wafer is supported such that the center of the wafer is located inside a virtual triangle formed by connecting the first intake hole, the second intake hole, and the third intake hole. The first suction part and the second suction part comprise a closed-figure first projection part and a closed-figure second projection part, respectively. The first projection part and the second projection part each include a circular arc projection part which is formed in a circular arc shape centered about a point located inside the virtual triangle.

### TECHNICAL FIELD

The present invention relates to a wafer conveyance robot.

### BACKGROUND ART

There is a wafer warped in a concentric manner as a wafer to be subjected to a semiconductor inspection. In addition, a wafer conveyance robot on which a hand having a vacuum adsorption unit is mounted may be used to convey a wafer. When conveying a warped wafer, if the adsorption unit is flat, a gap is likely to be formed between the wafer and the adsorption unit. Then, air continues to flow in from the gap between the wafer and the adsorption unit during vacuum adsorption, resulting in an adsorption error. As a method of avoiding such an adsorption error, there is a robot hand including an adsorption cup on an adsorption unit (for example, see PTL 1).

According to PTL 1, since the adsorption unit is provided with the adsorption cup, the adsorption cup can be deformed to conform the wafer, and the adsorption error can be avoided to some extent.

### CITATION LIST

### Patent Literature

PTL 1: JP2017-45784A

### SUMMARY OF INVENTION

### Technical Problem

However, the wafer conveyance robot in the related art has a problem that it is difficult to perform stable three-point support while reducing the adsorption error.

For example, in the configuration of PTL 1, by providing the adsorption cup on the adsorption unit, a thickness of the entire hand increases, the wafer cannot be inserted deep into a cassette, and the stable three-point support cannot be performed. In consideration of a weight of the warped wafer, when the wafer is supported at two points near a front of the cassette, a bending moment due to cantilever support is applied to the adsorption unit, and thus the wafer is easily separated from the adsorption unit. In addition, when the support is performed by the adsorption cup, an adsorption position may vary due to an adsorption force or vibration, which leads to a wafer positioning error in subsequent processing. Further, when a shape of the adsorption unit is an ellipse, an area of the adsorption unit cannot be maximized due to a geometric relationship to be described later, and there remains a possibility of the adsorption error.

The invention has been made to solve such a problem, and an object of the invention is to provide a wafer conveyance robot capable of performing stable three-point support while maintaining an adsorption force.

### Solution to Problem

An example of a wafer conveyance robot according to the invention is
a wafer conveyance robot that vacuum-adsorbs and conveys a wafer,
the wafer conveyance robot includes: a hand configured to support a wafer.

The hand includes
a first finger and a second finger,
a first adsorption unit provided on the first finger,
a second adsorption unit provided on the second finger, and,
a third adsorption unit provided on a connection portion connecting the first finger and the second finger.

The first adsorption unit, the second adsorption unit, and the third adsorption unit include a first intake hole, a second intake hole, and a third intake hole, respectively,
the wafer is supported such that a center of the wafer is located inside a virtual triangle formed by connecting the first intake hole, the second intake hole, and the third intake hole,
the first adsorption unit and the second adsorption unit respectively include a first protrusion and a second protrusion having a closed-figure shape, and
the first protrusion and the second protrusion each include a circular arc protrusion having a center at a point located inside the virtual triangle.

### Advantageous Effects of Invention

The wafer conveyance robot according to the invention can perform stable three-point support while maintaining an adsorption force.

### BRIEF DESCRIPTION OF DRAWINGS

FIG. 1 is a perspective view of a configuration including a wafer conveyance robot according to Embodiment 1 of the invention.

FIG. 2 is a diagram showing a relationship between a wafer 1 and a second adsorption unit 8.

FIG. 3 is a diagram showing a positional relationship between a hand 4 and a wafer chuck 16.

FIG. 4 is a diagram showing a relationship between a shape of an adsorption unit and a maximum gap between the wafer and the adsorption unit.

FIG. 5 is a diagram showing an overall structure of the hand 4 according to Embodiment 1.

FIG. 6 is a diagram showing a structure of an adsorption unit of a wafer conveyance robot according to Embodiment 2.

FIG. 7 is a diagram showing a structure of an adsorption unit of a wafer conveyance robot according to Embodiment 3.

FIG. 8 is a diagram showing a structure of an adsorption unit of a wafer conveyance robot according to Embodiment 4.

FIG. 9 is a diagram showing a structure of the hand 4 according to Embodiment 5.

### DESCRIPTION OF EMBODIMENTS

Hereinafter, embodiments of the invention will be described with reference to the accompanying drawings.

### Embodiment 1

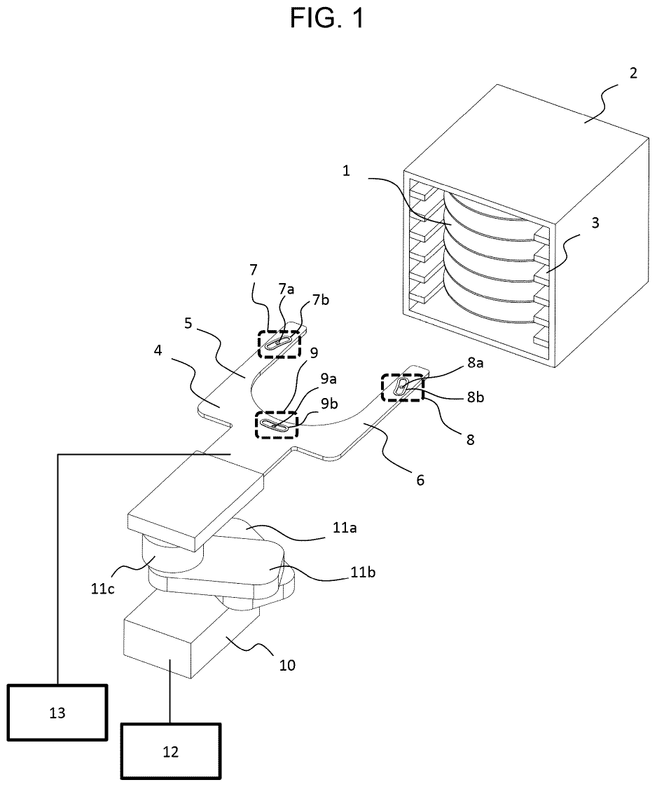

FIG. 1 is a perspective view of a configuration including a wafer conveyance robot according to Embodiment 1 of the invention. The wafer conveyance robot can vacuum-adsorb and convey a wafer 1 as a subject to be conveyed. The wafer conveyance robot can take the wafer 1 in and out of a cassette 2. The cassette 2 that stores the wafer 1 has a structure in which the wafer 1 is supported by left and right wafer holding units 3, and can have a shelf-shaped structure in which a plurality of wafer holding units 3 are connected in a vertical direction.

The wafer conveyance robot includes a hand 4 that supports the wafer 1. The hand 4 can handle the wafer 1. The hand 4 includes a first finger 5 and a second finger 6, a first adsorption unit 7 provided on the first finger 5, a second adsorption unit 8 provided on the second finger 6, and a third adsorption unit 9 provided on a connection portion connecting the first finger 5 and the second finger 6.

The first adsorption unit 7, the second adsorption unit 8, and the third adsorption unit 9 have a first intake hole 7a, a second intake hole 8a, and a third intake hole 9a, respectively. The first adsorption unit 7 and the second adsorption unit 8 include a first protrusion 7b and a second protrusion 8b, respectively, having a closed-figure shape. In addition, as shown in FIG. 1 and the like, the third adsorption unit 9 may similarly include a third protrusion 9b having a closed-figure shape.

The wafer conveyance robot may include, as actuators, a vertical actuator 10, a first rotary actuator 11a, a second rotary actuator 11b, and a third rotary actuator 11c. The hand 4 may be positioned by these actuators. The wafer conveyance robot may include a control unit 12, and the control unit 12 may control these actuators.

An operation example when the wafer conveyance robot takes out the wafer 1 from the cassette 2 will be described below.

The wafer conveyance robot moves the hand 4 using the first rotary actuator 11a, the second rotary actuator 11b, and the third rotary actuator 11c, thereby inserting the hand 4 in a horizontal direction into a gap between the wafer 1 as a subject to be conveyed and the wafer 1 one below the wafer 1 as a subject to be conveyed. Then, the hand 4 is moved to a position where a center of a triangle connecting the first adsorption unit 7, the second adsorption unit 8, and the third adsorption unit 9 formed on the hand 4 coincides with a center of the wafer 1, and the hand 4 is stopped there.

Subsequently, the wafer conveyance robot moves the hand 4 vertically upward by the vertical actuator 10 until the wafer 1 is completely separated from the wafer holding unit 3. At this time, the wafer 1 is lifted by the protrusions (for example, the first protrusion 7b, the second protrusion 8b, and the third protrusion 9b) provided in the adsorption unit.

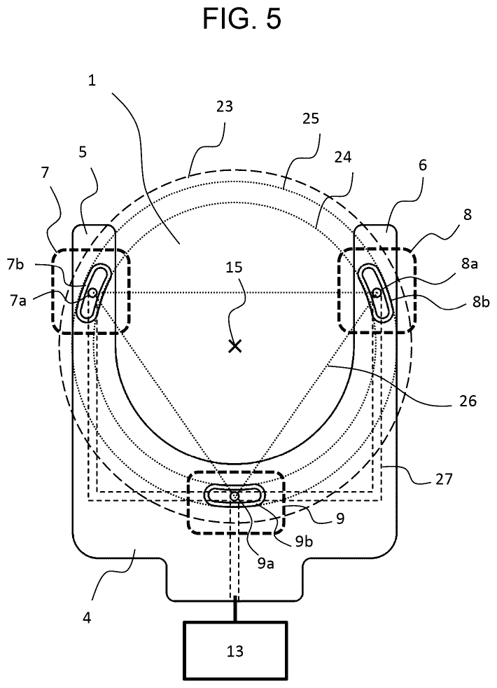

The wafer conveyance robot includes a vacuum pump 13. The wafer conveyance robot operates the vacuum pump 13 in a state in which the wafer 1 is lifted by the first protrusion 7b, the second protrusion 8b, and the third protrusion 9b formed on the first adsorption unit 7, the second adsorption unit 8, and the third adsorption unit 9. In this manner, air is exhausted from the first intake holes 7a, the second intake holes 8a, and the third intake holes 9a through air passages (described later with reference to FIG. 5 and the like) inside the hand 4, air between the wafer 1 and the hand 4 in each adsorption unit is removed, and the wafer 1 is adsorbed and supported by the hand 4.

The wafer conveyance robot pulls out the hand 4 from the cassette 2 in the horizontal direction in a state in which the wafer 1 is adsorbed and supported by the hand 4 in this manner, and conveys the hand 4 to a position for subsequent processing.

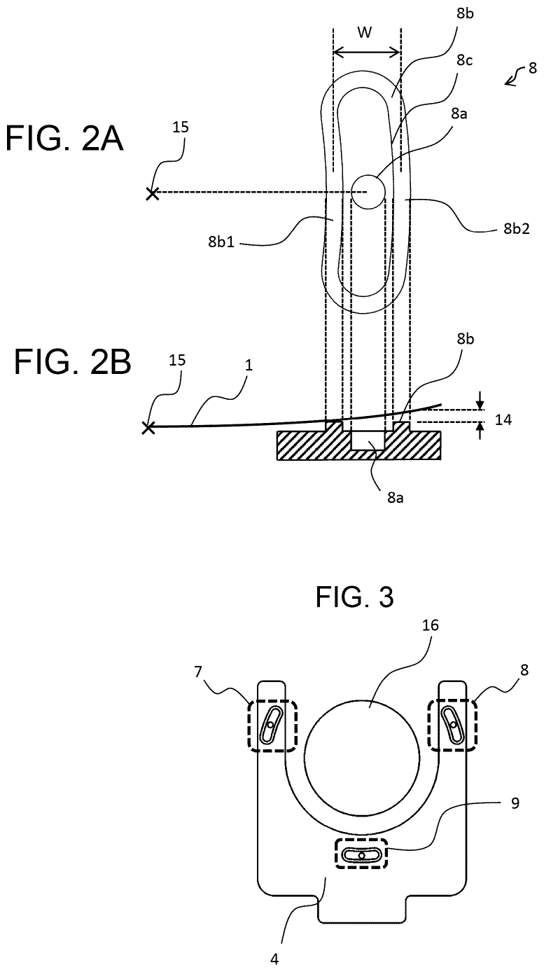

Operations of the wafer conveyance robot according to the present embodiment will be described with reference to FIGS. 2 and 3. As an example, a case in which a wafer warped downward in a convex shape in a concentric manner is adsorbed to the second adsorption unit 8 of the hand 4 will be described.

FIG. 2 shows a relationship between the wafer 1 and the second adsorption unit 8. (a) of FIG. 2 is a plan view of the second adsorption unit 8. A position of a wafer center 15 is shown. (b) of FIG. 2 is a cross-sectional view taken along a plane passing through the wafer center 15 and a center of the second intake hole 8a in FIG. 2. The wafer 1 warped downward in the convex shape in the concentric manner is shown.

The second protrusion 8b of the second adsorption unit 8 includes a first arc protrusion 8b1 having a first radius and a second arc protrusion 8b2 having a second radius larger than the first radius.

When the warped wafer 1 is supported by the hand 4, a gap 14 is formed between the second adsorption unit 8 (particularly, the second arc protrusion 8b2 ) and the wafer 1. If the gap 14 is too large, air is continuously supplied from the outside to the inside of the second intake hole 8a through the gap 14 when air is exhausted from the second intake hole 8a, and thus vacuum adsorption cannot be performed and an adsorption error occurs.

In order to prevent the above, it is effective to provide an adsorption unit at a position where a relative angle with respect to a surface of the hand 4 is small (for example, near a center portion of the wafer), or to reduce a width W of the second protrusion 8b (width in a radial direction of the wafer 1).

Here, as shown in FIG. 3, it is preferable that the hand 4 and the adsorption units are disposed at positions avoiding the center portion of the wafer 1.

A positional relationship between the hand 4 and a wafer chuck 16 will be described with reference to FIG. 3. In order to avoid interference with the wafer chuck 16 as a wafer delivery destination, the hand 4 (including the first adsorption unit 7, the second adsorption unit 8, and the third adsorption unit 9) is preferably disposed outside a region of the wafer chuck 16. In a semiconductor inspection, the wafer 1 may be rotated at high speed, and it is preferable to secure a maximum contact area between the wafer 1 and the wafer chuck 16 in order to implement stable rotation.

Therefore, the first adsorption unit 7, the second adsorption unit 8, and the third adsorption unit 9 are preferably provided near an outer peripheral portion of the wafer 1 of the hand 4, but a relative angle of the warpage of the wafer 1 increases near the outer peripheral portion of the wafer 1.

In addition, in the example of FIG. 2, when an area surrounded by an inner periphery 8c of the second protrusion 8b is reduced, an adsorption force is reduced, and a risk that the wafer 1 falls during wafer conveyance increases, and thus it is preferable to increase an area of a region surrounded by the inner periphery 8c.

Therefore, when an adsorption unit structure in which the width W is minimized while increasing the area of the region surrounded by the inner periphery 8c is adopted, the risk that the wafer falls can be reduced while avoiding the interference with the wafer chuck 16.

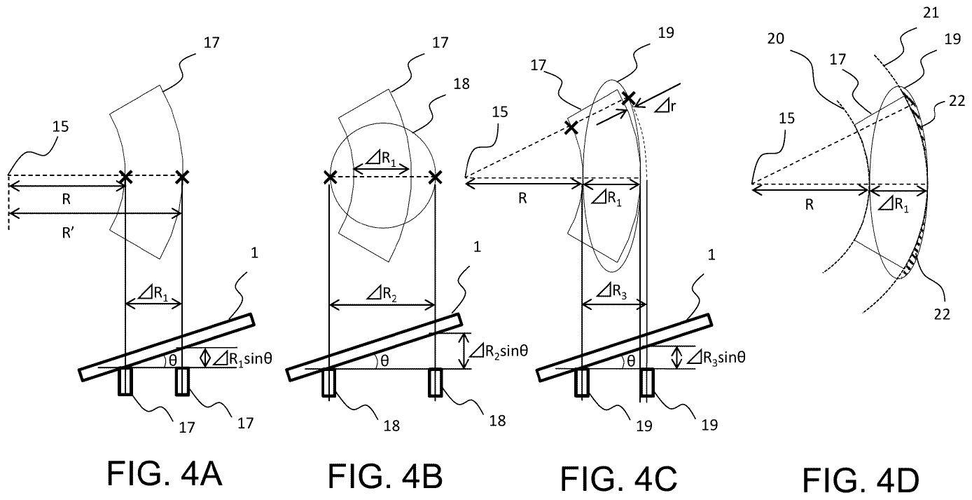

With reference to FIG. 4, a relationship between a shape of the adsorption unit (particularly, a protrusion) and a maximum gap between the wafer and the adsorption unit will be described. (a) of FIG. 4 shows an example in which the shape of the protrusion is a closed-figure shape 17 having two arcs concentric with an outer periphery of the wafer. (b) of FIG. 4 shows an example in which the shape of the protrusion is a circle 18. (c) and (d) of FIG. 4 show an example in which the shape of the protrusion is an ellipse 19. (a) to (c) of FIG. 4 show the closed-figure shape 17 in an overlapping manner for comparison.

In (a) to (c) of FIG. 4, a plan view for showing the shape of the protrusion and a cross-sectional view showing a positional relationship between the wafer and the protrusion are shown together.

In order to simplify the description, the following conditions are assumed.
The closed-figure shape 17, the circle 18, and the ellipse 19 all have the same area (adsorption area)
The warped shape of the wafer 1 is approximated by a straight line near an adsorption region
ΔR1 to ΔR3 in the drawing are distances between the following (1) and (2)
(1) Contact point between wafer and protrusion
(2) Point where maximum gap is generated between wafer and protrusion
θ is an angle of the warpage of the wafer with respect to a horizontal plane

Points corresponding to the above (1) and (2) are indicated by a symbol “x” in plan views of (a) to (c) of FIG. 4. The cross-sectional views of (a) to (c) of FIG. 4 are based on planes passing through the points corresponding to (1) and (2), respectively.

In the example of (a) of FIG. 4, the protrusion includes an arc-shaped portion (arc protrusion). In this example, ΔR1 is a distance (difference in radius) between two arcs in the closed-figure shape 17. Distances R and R′ between the arcs and the wafer center 15 are constant regardless of a position in a wafer circumferential direction. Therefore, ΔR1 is also constant, and the maximum gap is ΔR1 sin θ.

In (b) of FIG. 4, ΔR2 coincides with a diameter of the circle 18. Here, when it is assumed that the diameter of the circle 18 coincides with ΔR1, since the entire region surrounded by the circle is included in the closed-figure shape 17, an area of the circle is smaller than that of the closed-figure shape 17. Therefore, in order to equalize areas of the closed-figure shape 17 and the circle 18 according to the assumption, it is necessary to satisfy at least ΔR2>ΔR1. Therefore, a relationship of the maximum gap is ΔR2 sin θ>ΔR1 sin θ.

In (c) of FIG. 4, when the radius of one of the two arcs of the closed-figure shape 17 close to the wafer center 15 is R and the radius away from the wafer center 15 is R+ΔR1, a part of the region surrounded by the ellipse 19 deviates from a region surrounded by the radius R+ΔR1. If a shortest distance between a point in this deviation region that is farthest from the wafer center and the circle having radius R+ΔR1 is taken as Δr, then ΔR=ΔR1+Δr in (c) of FIG. 4 can be written. Therefore, the relationship of the maximum gap is ΔR3 sin θ>ΔR1 sin θ.

According to the examination of (a) to (c) of FIG. 4, a gap (or an area of the gap) is minimized in the case of (a) of FIG. 4, that is, in the case in which a shape of the protrusion is the closed-figure shape 17.

In the example of (a) of FIG. 4, the closed-figure shape 17 includes straight line portions connecting two arcs, but this portion does not need to be a straight line, and for example, as in the second protrusion 8b shown in (a) of FIG. 2, two arcs may be connected by two semicircular shapes. Also in this case, since ΔR1 in (a) of FIG. 4 is unchanged, there is no difference between comparison results of (a) to (c) of FIG. 4.
(d) of FIG. 4 shows a relationship between the shape of the protrusion and the maximum gap between the wafer and the adsorption unit. On a periphery of a circle 20 having the radius R, a height of the warped shape of the wafer warped in the concentric manner is constant. Similarly, the height of the warped shape of the wafer is also constant on a periphery of a circle 21 having the radius R+ΔR1. When the shape of the protrusion is the closed-figure shape 17, a back surface of the wafer warped in the concentric manner overlaps the protrusion without a gap along the periphery thereof, or is close to the protrusion, so that a gap with the protrusion is small. Accordingly, an air leakage is reduced.

On the other hand, when the protrusion is the circle 18 or the ellipse 19 as a comparative example, the height of the warped shape of the wafer and the height of the protrusion do not coincide with each other in a region (for example, a region 22 in a case where the shape of the adsorption unit is the ellipse 19) deviated from the periphery having a constant radius, and a gap is likely to occur, which causes the leakage. According to the closed-figure shape 17 in FIG. 4 or the shape of the second protrusion 8b in FIG. 2, such a situation can be avoided.

FIG. 5 shows an overall structure of the hand 4 according to the present embodiment. FIG. 5 shows a plan view including the hand 4 and the wafer 1. The hand 4 has the first finger 5 and the second finger 6, and has the first adsorption unit 7 at or near an end portion of the first finger 5, the second adsorption unit 8 at or near an end portion of the second finger 6, and the third adsorption unit 9 at a connection portion (root portion) connecting the first finger 5 and the second finger 6.

The wafer 1 is supported such that the wafer center 15 of the wafer 1 is located inside a virtual triangle 26 (virtual triangle) formed by connecting the first intake hole 7a, the second intake hole 8a, and the third intake hole 9a. When the first intake hole 7a, the second intake hole 8a and/or the third intake hole 9a cannot be regarded as points, positions of the intake holes may be defined as appropriate, and may be interpreted as, for example, centers of gravity of the intake holes on a plan view.

The first protrusion 7b, the second protrusion 8b, and the third protrusion 9b have a closed-figure shape including a protrusion (arc protrusion) forming an arc centered on the wafer center 15. A center of the arc does not need to coincide with the wafer center 15 as long as the center is a point located inside the virtual triangle 26, and the position of the wafer center 15 when the wafer 1 is actually conveyed may be shifted within a predetermined allowable range.

In particular, in the example of FIG. 5, the first protrusion 7b includes an inner arc protrusion (that is, a first arc protrusion along a virtual circle 24 concentric with an outer periphery 23 of the wafer 1 and having a first radius) and an outer arc protrusion (that is, a second arc protrusion along a virtual circle 25 concentric with the outer periphery 23 of the wafer 1 and having a second radius larger than the first radius). Similarly, the second protrusion 8b includes the first arc protrusion along the virtual circle 24 and the second arc protrusion along the virtual circle 25. Further, the third protrusion 9b also includes the first arc protrusion along the virtual circle 24 and the second arc protrusion along the virtual circle 25.

The first protrusion 7b, the second protrusion 8b, and the third protrusion 9b protrude in a front direction of a paper surface of FIG. 5, and the wafer 1 is supported in contact with the protrusions.

The first intake hole 7a, the second intake hole 8a, and the third intake hole 9a communicate with an air passage 27 formed inside the hand 4, and air in each intake hole is exhausted by the vacuum pump 13.

In this manner, by disposing each of the protrusions of the adsorption units along the virtual circles 24 and 25, it is possible to maximize the area surrounded by the inner periphery of each protrusion while reducing the width (width in a wafer radial direction) of each protrusion. Accordingly, it is possible to reduce the gap between the adsorption unit and the wafer while maintaining the adsorption force.

In particular, since each protrusion has a total of two arc protrusions on both sides, the height of the protrusions on both sides of each adsorption unit well coincides with the height of the warped shape of the wafer, and the wafer 1 can be adsorbed well.

As described above, the wafer conveyance robot according to the present embodiment can perform stable three-point support while maintaining the adsorption force.

### Embodiment 2

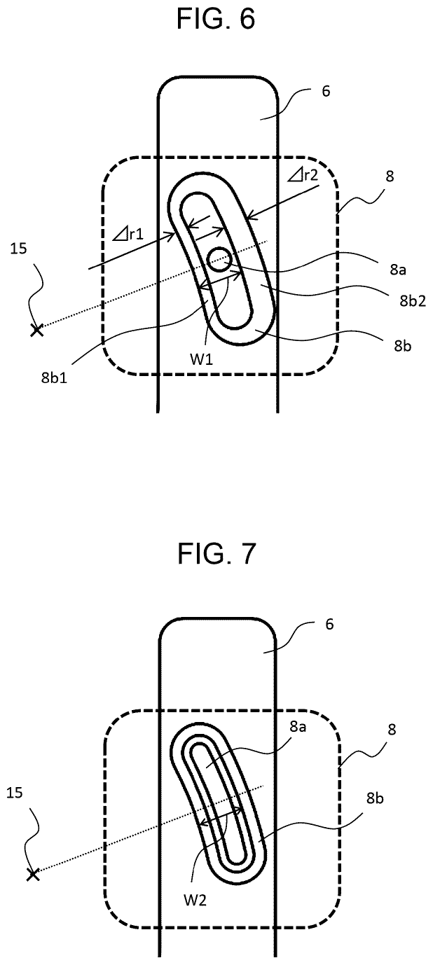

FIG. 6 is a diagram showing a structure of an adsorption unit of a wafer conveyance robot according to Embodiment 2. FIG. 6 shows the second adsorption unit 8 of the second finger 6 and surroundings thereof. Hereinafter, description of parts common to Embodiment 1 may be omitted.

The second protrusion 8b of the second adsorption unit 8 includes the first arc protrusion 8b1 having the first radius and the second arc protrusion 8b2 having the second radius larger than the first radius. A width ΔR2 (radial width) of the second arc protrusion 8b2 is larger than a width ΔR1 (radial width) of the first arc protrusion 8b1. That is, in the second protrusion 8b, the width ΔR2 on the side far from the wafer center 15 is larger than the width Δr1 on the side close to the wafer center 15.

In the example of FIG. 6, a width of each of the first arc protrusion 8b1 and the second arc protrusion 8b2 is constant, but the width may not be constant. When the width is not constant, a maximum width of the second arc protrusion 8b2 may be larger than a maximum width of the first arc protrusion 8b1.

Structures of the first protrusion 7b and the third protrusion 9b may be the same as that of the second protrusion 8b.

By increasing Δr1 and ΔR2, it is possible to increase ventilation resistance between the wafer and the protrusion, so that the adsorption force can be increased. On the other hand, when Δr1 is increased, the distance W1 in the wafer radial direction in the protrusion increases, and thus the maximum gap between the wafer and the protrusion increases.

Therefore, as shown in FIG. 6, by reducing only Δr1 that affects the maximum gap and increasing ΔR2 that does not affect the maximum gap, it is possible to increase the adsorption force while reducing the maximum gap.

Note that, while the wafer and the protrusion are in contact with each other in the first arc protrusion 8b1, a gap is generated in the second arc protrusion 8b2 , and thus an inflow of air during vacuum evacuation occurs in the second arc protrusion 8b2 . It is also effective to increase the width ΔR2 of the second arc protrusion 8b2 from the viewpoint of increasing the ventilation resistance only for the inflow air as a subject.

### Embodiment 3

FIG. 7 is a diagram showing a structure of an adsorption unit of a wafer conveyance robot according to Embodiment 3. FIG. 7 shows the second adsorption unit 8 of the second finger 6 and the surroundings thereof. Hereinafter, description of parts common to Embodiment 1 or 2 may be omitted.

In Embodiment 3, the second intake hole 8a has a shape extending in a circumferential direction along the shape of the second protrusion 8b. For example, the second intake hole 8a is formed in an arc shape. More strictly, the second intake hole 8a includes a portion forming an arc having a constant width (concentric with the arc related to the second protrusion 8b).

In general, the adsorption force can be increased by increasing a size of the intake hole, but when the intake hole is the circle, a distance W2 in the wafer radial direction increases as the diameter increases, and the gap area increases.

On the other hand, as shown in FIG. 7, when the intake hole has a shape (arc shape) extending in the circumferential direction, it is possible to increase the area of the intake hole and increase the adsorption force while reducing the distance W2 in the wafer radial direction.

Structures of the first intake hole 7a and the third intake hole 9a may be the same as that of the second intake hole 8a.

### Embodiment 4

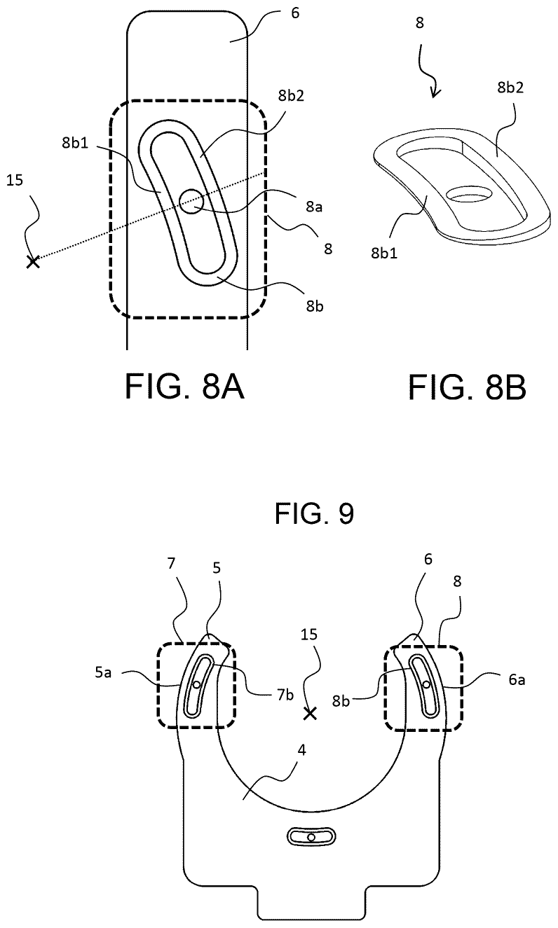

FIG. 8 is a diagram showing a structure of an adsorption unit of a wafer conveyance robot according to Embodiment 4. FIG. 8 shows the second adsorption unit 8 of the second finger 6 and the surroundings thereof. Hereinafter, description of parts common to Embodiments 1 to 3 may be omitted.
(a) of FIG. 8 is a plan view, and (b) of FIG. 8 is a perspective view. A height of the second arc protrusion 8b2 is larger than a height of the first arc protrusion 8b1. Here, a “height” refers to a dimension in a depth direction of a paper surface in (b) of FIG. 8.

By providing a height difference between the protrusions in this manner, the shape of the wafer warped downward in the convex shape in the concentric manner follows the shape of the protrusions, and the gap between the wafer and the protrusions can be reduced. The height difference can be determined based on, for example, an amount of the warpage of the wafer as a subject to be conveyed.

In the example of FIG. 8, the height of each of the first arc protrusion 8b1 and the second arc protrusion 8b2 is constant, but the height may not be constant. When the height is not constant, a maximum height of the second arc protrusion 8b2 may be larger than a maximum height of the first arc protrusion 8b1.

### Embodiment 5

FIG. 9 shows a structure of the hand 4 according to Embodiment 5. Hereinafter, description of parts common to Embodiments 1 to 4 may be omitted.

In the example of FIG. 9, parts of the first finger 5 and the second finger 6 are expanded in accordance with the shapes of the first adsorption unit 7 and the second adsorption unit 8. In particular, at least a part of the outer periphery of each of the first finger 5 and the second finger 6 forms an arc. Specifically, the first finger 5 has a first arc portion 5a at a portion forming an outer side of the hand 4, and the second finger 6 has a second arc portion 6a at a portion forming the outer side of the hand 4. The center of the first arc portion 5a and the second arc portion 6a can be the wafer center 15 (or the center of the arc of the first protrusion 7b and the second protrusion 8b).

With such a shape of the finger, the adsorption unit can be enlarged without changing the width of the adsorption unit in the radial direction, and can be extended, for example, in the circumferential direction. Accordingly, it is possible to increase the area of the adsorption unit and improve the adsorption force without increasing the gap between the wafer and the protrusion.

### Modifications

Two or more of the above-described Embodiments 1 to 5 may be combined.

In Embodiments 1 to 5, each protrusion may include a total of two arc protrusions on both sides (for example, the first arc protrusion 8b1 and the second arc protrusion 8b2 in FIG. 2), and only one of the arc protrusions may have a shape other than an arc (for example, a straight line or an ellipse).

Further, in each protrusion, a shape of a portion connecting an inner portion (for example, the first arc protrusion 8b1) and an outer portion (for example, the second arc protrusion 8b2 ) can be appropriately changed. In the example of FIG. 2, each of the two connection portions has a semicircular shape, but each of the two connection portions may have a linear shape as shown in FIG. 4, or may have a shape other than these.

### REFERENCE SIGNS LIST

1: wafer
2: cassette
3: wafer holding unit
4: hand
5: first finger
5a: first arc portion
6: second finger
6a: second arc portion
7: first adsorption unit
7a: first intake hole
7b: first protrusion
8: second adsorption unit
8a: second intake hole
8b: second protrusion
8b1: first arc protrusion
8b2: second arc protrusion
8c: inner periphery of second protrusion
9: third adsorption unit
9a: third intake hole
9b: third protrusion
10: vertical actuator
11a: first rotary actuator
11b: second rotary actuator
11c: third rotary actuator
12: control unit
13: vacuum pump
14: gap
15: wafer center
16: wafer chuck
17: closed-figure shape
18: circle
19: ellipse
20: circle
21: circle
22: region
23: outer periphery
24: virtual circle
25: virtual circle
26: virtual triangle (virtual triangle)
27: air passage

1. A wafer conveyance robot that vacuum-adsorbs and conveys a wafer, the wafer conveyance robot comprising:
a hand configured to support a wafer, wherein
the hand includes
a first finger and a second finger,
a first adsorption unit provided on the first finger,
a second adsorption unit provided on the second finger, and
a third adsorption unit provided on a connection portion connecting the first finger and the second finger,
the first adsorption unit, the second adsorption unit, and the third adsorption unit include a first intake hole, a second intake hole, and a third intake hole, respectively,
the wafer is supported such that a center of the wafer is located inside a virtual triangle formed by connecting the first intake hole, the second intake hole, and the third intake hole,
the first adsorption unit and the second adsorption unit respectively include a first protrusion and a second protrusion having a closed-figure shape, and
the first protrusion and the second protrusion each include a circular arc protrusion having a center at a point located inside the virtual triangle.

2. The wafer conveyance robot according to claim 1, wherein
the first protrusion and the second protrusion each include a first arc protrusion having a first radius and a second arc protrusion having a second radius larger than the first radius.

3. The wafer conveyance robot according to claim 2, wherein
a radial width of the second arc protrusion is larger than a radial width of the first arc protrusion.

4. The wafer conveyance robot according to claim 1, wherein
the first intake hole and the second intake hole are formed in an arc shape.

5. The wafer conveyance robot according to claim 2, wherein
a height of the second arc protrusion is larger than a height of the first arc protrusion.

6. The wafer conveyance robot according to claim 1, wherein
at least a part of outer peripheries of the first finger and the second finger forms an arc.
